(19) United States
(12) Patent Application Publication
(10) Pub. No.: US 2026/0114201 A1
(43) Pub. Date: Apr. 23, 2026

(54) METHOD OF MANUFACTURING SEMICONDUCTOR DEVICE

(71) Applicant: Taipei ANJET Corporation, Taipei (TW)

(72) Inventors: Hsin Hong SHIH, Taipei (TW); Wen-Chin WU, Taipei (TW)

(21) Appl. No.: 18/922,403

(22) Filed: Oct. 22, 2024

(51) Int. Cl. H01L 21/311; H01L 29/47; H01L 29/66

(52) U.S. Cl. CPC H10P 50/73; H10D 30/015; H10D 30/6738; H10D 30/675; H10D 62/85; H10D 64/64; H10P 50/283

(57) ABSTRACT

Disclosed is a method of manufacturing a semiconductor device including: growing a buffer layer, a channel layer, and a barrier layer on a substrate layer sequentially; forming a gate contact on the barrier layer; forming a first dielectric layer, and a first photoresist layer over the gate contact and the barrier layer sequentially; patterning the first photoresist layer to form a first photoresist mask with a hole pattern; performing a first wet etching, a dry etching, and a second wet etching using the hole pattern to etch the first dielectric layer to form an opening exposing a portion of the gate contact; stripping the first photoresist mask; forming a gate metal layer to cover the first dielectric layer and fill the gate contact opening; patterning the gate metal layer to form a gate electrode connected to the gate contact and a gate field plate connected to the gate electrode.

### TECHNICAL FIELD

The present disclosure relates to the field of semiconductor processing, and in particular to a method of manufacturing a semiconductor device.

### RELATED ART

The high electron mobility transistor (HEMT) fabricated from Gallium nitride-based (GaN-based) materials has various advantages in electrical, mechanical, and chemical aspects of the field due to the characteristics of the GaN-based materials, such as a high thermal resistance, chemical inertness, a wide band-gap, and a high electron mobility.

The performance of the existing HEMT may be affected by a process in manufacturing. Specially, only dry etching is used to etch the interlayer dielectric (ILD) layer to form the gate electrode of the existing HEMT, resulting in the damage of the gate contact of the HEMT, and the worse field plate effect due to non-flatness of the ILD layer of the HEMT.

### SUMMARY

The present disclosure provides a method of manufacturing a semiconductor device, which can solve the problem of the damage of the gate contact and the worse field plate effect due to non-flatness of the ILD layer since the existing HEMT only uses a dry etching process to etch the ILD layer to form the gate electrode.

In order to solve the above technical problem, the present disclosure is implemented as follows.

According to an aspect of the present disclosure, the present disclosure provides a method of manufacturing a semiconductor device, which includes: growing a buffer layer, a channel layer, and a barrier layer on a substrate layer in order; forming a gate contact on a portion of the barrier layer; forming a first dielectric layer, and a first photoresist layer over the gate contact and the barrier layer not covered by the gate contact in order; patterning the first photoresist layer to form a first photoresist mask with a hole pattern; performing a first wet etching process, a dry etching process, and a second wet etching process using the hole pattern to etch the first dielectric layer in order to form a gate contact opening which exposes a portion of the gate contact; stripping the first photoresist mask; forming a gate metal layer to cover the first dielectric layer and fill the gate contact opening; and patterning the gate metal layer to form a gate electrode connected to the gate contact and a gate field plate connected to the gate electrode.

In the embodiment of the present disclosure, based on the anisotropic characteristic of the dry etching process and the isotropic characteristic of the first wet etching process and the second wet etching process, performing the first wet etching process, the dry etching process, and the second wet etching process on the first dielectric layer using the hole pattern in order can not only form the gate contact opening exposes the portion of the gate contact, but also flatten and thin the first dielectric layer near the gate contact, thereby avoiding the damage of the gate contact, increasing the field plate effect and improving the performance of the semiconductor device.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 to FIG. 9 are cross-sectional views illustrating a method of manufacturing a semiconductor device according to an embodiment of the present disclosure; and

FIG. 10 to FIG. 18 are cross-sectional views illustrating that a source electrode and a drain electrode are formed on opposite sides of the gate contact in a method of manufacturing a semiconductor device according to an embodiment of the present disclosure.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

In the following description and in the claims, the terms “include/including” and “comprise/comprising” are used in an open-ended fashion, and thus should be interpreted as “including but not limited to”. Therefore, a process, method, object, or device that includes a series of elements not only includes these elements, but also includes other elements not specified expressly, or may include inherent elements of the process, method, object, or device.

It must be understood that when a component is described as being “connected” or “coupled” to (or with) another component, it may be directly connected or coupled to other components or through an intermediate component. In contrast, when a component is described as being “directly connected” or “directly coupled” to (or with) another component, there are no intermediate components.

Additionally, the terms “about”, and “approximately” are normally interpreted as being within 10% of a given value or range, or as being within 5%, 3%, 2%, 1%, or 0.5% of a given value or range.

Moreover, although the terms “first”, “second”, etc. may be used herein to describe various elements, these elements should not be limited by these terms. These terms are only used to distinguish one element from another.

In the following embodiment, the same reference numerals are used to refer to the same or similar elements throughout the disclosure.

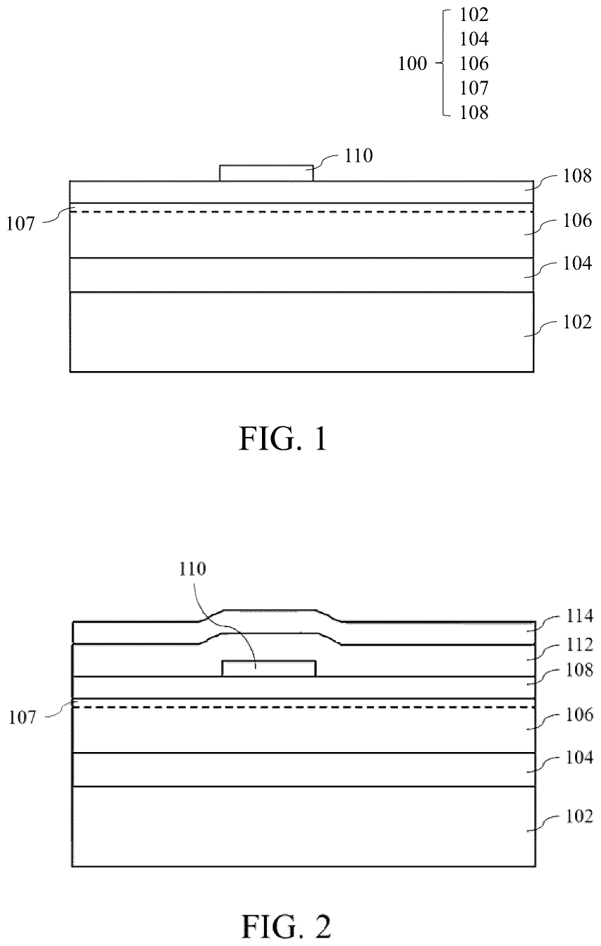

FIG. 1 to FIG. 9 are cross-sectional views illustrating a method of manufacturing a semiconductor device according to an embodiment of the present disclosure. The semiconductor device is a HEMT. Referring to FIG. 1, a substrate structure 100 is provided, the substrate structure 100 comprises a substrate layer 102, a buffer layer 104, a channel layer 106, and a barrier layer 108, and the buffer layer 104, the channel layer 106, and the barrier layer 108 are grown on the substrate layer 102 in order.

The substrate layer 102 may include a semiconductor material (e.g., silicon or germanium), a compound semiconductors (e.g., GaAs, GaP, InP, InAs and/or InSb), an alloy semiconductor (e.g., SiGe, GaAsP, AlInAs, AlGaAs, GaInAs, GaInP, and/or GaInAsP), or a combination thereof. In some embodiments, the substrate layer 102 may include a silicon-on-insulator (SOI) substrate or a germanium-on-insulator (GOI) substrate.

The buffer layer 104 may be formed on the substrate layer 102 to act as a stress release layer to release stress formed in the features (e.g., the channel layer 106) above the substrate layer 102. The material of the buffer layer 104 may include aluminum gallium nitride (AlGaN), aluminum nitride (AlN), or a combination thereof. The buffer layer 104 may be formed by an epitaxial growth process, such as metal organic chemical vapor deposition (MOCVD), hydride vapor phase epitaxy (HVPE), molecular beam epitaxy (MBE), a combination thereof, or the like.

The material of the channel layer 106 may include a binary compound semiconductor of group III-V, such as a nitride of group III. For example, the material of the channel layer 106 may be gallium nitride (GaN). The channel layer 106 may be formed by an epitaxial growth process, such as MOCVD, HVPE, MBE, a combination thereof, or the like.

The material of the barrier layer 108 may include a ternary compound semiconductor of group III-V. For example, the material of the barrier layer 108 may be AlGaN, aluminum indium nitride (AlInN), or a combination thereof. The barrier layer 108 may be formed by an epitaxial growth process, such as MOCVD. HVPE, MBE, a combination thereof or a similar process. In some embodiments, the material of the channel layer 106 is different from that of the barrier layer 108, and thereby the interface between the channel layer 106 and the barrier layer 108 is a heterojunction structure. Due to the difference in energy gap between the channel layer 106 and the barrier layer 108, the spontaneous polarization and piezoelectric polarization effects of the channel layer 106 may generate a high concentration of electrons converging into the potential well, thereby forming a two-dimensional electron gas (2DEG) layer 107 near the surface of the channel layer 106. The 2DEG layer 107 may be a planar current channel region of the semiconductor device at on-state.

The material of a gate contact 110 may be p-doped III-V semiconductor, such as PGaN. The steps for forming the gate contact 110 on a portion of the barrier layer 108 may include: forming a p-doped III-V semiconductor layer on the barrier layer 108 thorough an epitaxial growth process, forming a patterned mask layer on the p-doped III-V semiconductor layer, performing an etching process on the p-doped III-V semiconductor layer to remove portions of the p-doped III-V semiconductor layer not covered by the patterned mask layer, and removing the patterned mask layer. The gate contact 110 is formed on the portion of the barrier layer 108 to facilitate “normally-off” or enhancement mode (E-mode) operation by creating a p-n junction depletion region, which extends to the 2DEG layer 107. Therefore, when no bias is applied to the gate contact 110, the 2DEG layer 107 is depleted of carriers, making the channel discontinuous, therefore preventing the flow of electrons from the source electrode to the drain electrode.

Referring to FIG. 2, a first dielectric layer 112, and a first photoresist layer 114 are formed over the gate contact 110 and the barrier layer 108 not covered by the gate contact 110 in order. The first dielectric layer 112 may be an inter-layer dielectric (ILD) layer. The material of the first dielectric layer 112 may include a low-k dielectric material, such as phosphosilicate glass (PSG), borophosphosilicate glass (BPSG), fluorosilicate glass (FSG), Spin-On-Glass, Spin-On-Polymers, silicon carbon material, a combination thereof, or the like. The first dielectric layer 112 may be formed by any suitable method, such as spin-on coating, CVD, plasma enhanced chemical vapor deposition (PECVD), PVD, or the like. The first photoresist layer 114 may include a photoresist material and a solvent, wherein the photoresist material includes a polymer. The first photoresist layer 114 may be deposited by spin-on coating or other suitable technique.

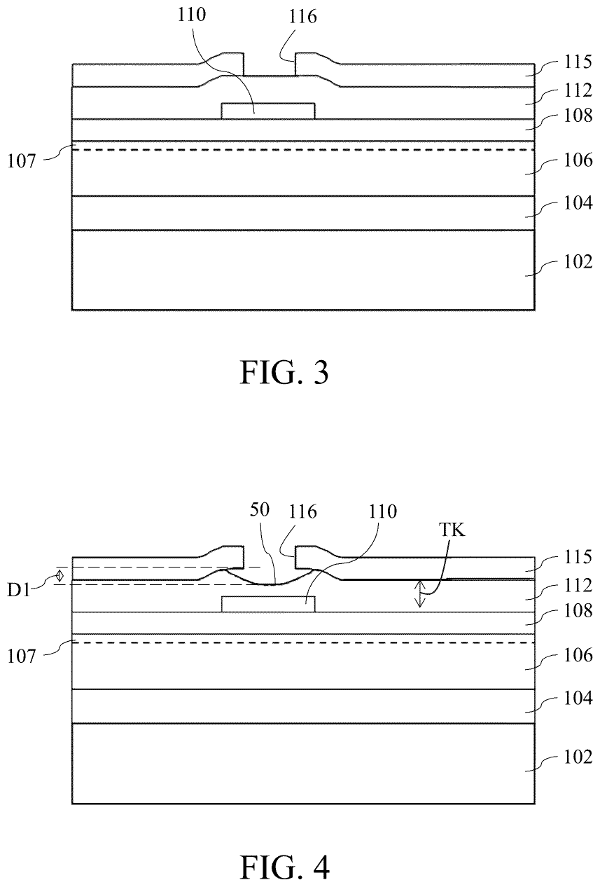

Referring to FIG. 3, the first photoresist layer 114 is patterned through exposure and development to form a first photoresist mask 115 with a hole pattern 116, wherein the hole pattern 116 of the first photoresist mask 115 are formed at a location corresponding to the gate contact 110. In some embodiments, the first photoresist mask 115 covers the first dielectric layer 112 with the hole pattern 116 exposing a portion of the first dielectric layer 112.

Referring to FIG. 4 to FIG. 6, which illustrate that a first wet etching process, a dry etching process, and a second wet etching process are performed using the hole pattern to etch the first dielectric layer in order. As shown in FIG. 4, the first wet etching process is performed using the hole pattern 116 to etch the first dielectric layer 112 to form a recess 50 in the first dielectric layer 112, wherein the first wet etching process can have the isotropic characteristic, the first wet etching process is used to smooth the un-flat first dielectric layer 112 near the gate contact 110, and the first wet etching process may be performed by using at least one of a hydrogen fluoride (HF) solution and a buffered oxide etchant (BOE). In some embodiments, the BOE may be a solution of HF/NH₄F in a volume ratio of 20:1 mixed with water. In some embodiments, the recess 50 may have a depth D1 between about twenty percent and about fifty percent of a thickness TK of the first dielectric layer 112.

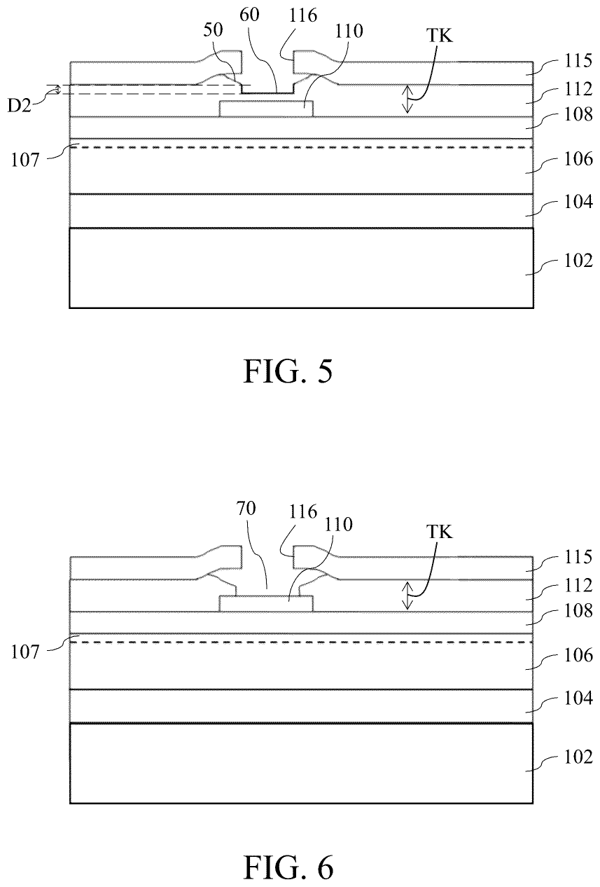

As shown in FIG. 5, the dry etching process is performed using the hole pattern 116 to etch the first dielectric layer 112 to form a trench 60 at the bottom of the recess 50 in the first dielectric layer 112, wherein the dry etching process can have the anisotropic characteristic, so that the dry etching process is used to prevent wide lateral etching. In some embodiments, the trench 60 may have a depth D2 between about thirty percent and about sixty percent of the thickness TK of the first dielectric layer 112.

As shown in FIG. 6, the second wet etching process is performed using the hole pattern 116 to etch a remaining thickness of the first dielectric layer 112 to form a gate contact opening 70 which exposes a portion of the gate contact 110, wherein the second wet etching process can have the isotropic characteristic, the second wet etching process is used to further smooth the un-flat first dielectric layer 112 near the gate contact 110, smooth the interface structure that caused by the first wet etching process, and prevent the damage to the gate contact 110, and the second wet etching process may be performed by using at least one of a HF solution and a BOE. In some embodiments, the buffered oxide etchant may be a solution of HF/NH₄F in a volume ratio of 20:1 mixed with water. In some embodiments, the remaining thickness of the first dielectric layer 112 is between about 20 percent and about 50 percent of the thickness TK of the first dielectric layer 112. In some embodiments, the second wet etching process is performed with a total time including an etching time and an over-etching time, the over-etching time is in a range from about fifty percent to about one hundred percent of the etching time (that is, the over-etching rate is from 50% to 100%), and the etching time is a time for etching a remaining thickness of the first dielectric layer 112 to form the gate contact opening 70.

It should be noted that the second wet etching process causes less damage to the gate contact 110 than the dry etching process may be performed, and the over-etching time is provided to ensure complete etching of the portion of the first dielectric layer 112 corresponding to the hole pattern 116. Based on the anisotropic characteristic of the dry etching process and the isotropic characteristic of the first wet etching process and the second wet etching process, the first dielectric layer 112 near the gate contact 110 in the present disclosure becomes flatter and thinner than only the dry etching process is performed on the first dielectric layer during the manufacturing process of the existing HEMT.

In some embodiments, a sum of an etched depth of the first dielectric layer 112 etched by the first wet etching process (i.e., the depth D1 of the recess 50) and an etched depth of the first dielectric layer 112 etched by the second wet etching process (i.e., the remaining thickness of the first dielectric layer 112) is from about forty percent to about seventy percent of the thickness TK of the first dielectric layer 112. By controlling the sum of the depth D1 of the recess 50 and the remaining thickness of the first dielectric layer 112, the flatness and thickness of the first dielectric layer 112 near the gate contact 110 can be controlled based on the isotropic characteristic of the first wet etching process and the second wet etching process. When the sum of the depth D1 of the recess 50 and the remaining thickness of the first dielectric layer 112 is from about forty percent to about seventy percent of the thickness TK of the first dielectric layer 112, a balance is struck between the flatness and thickness of the first dielectric layer 112 near the gate contact 110 and the electrical performance of the semiconductor device.

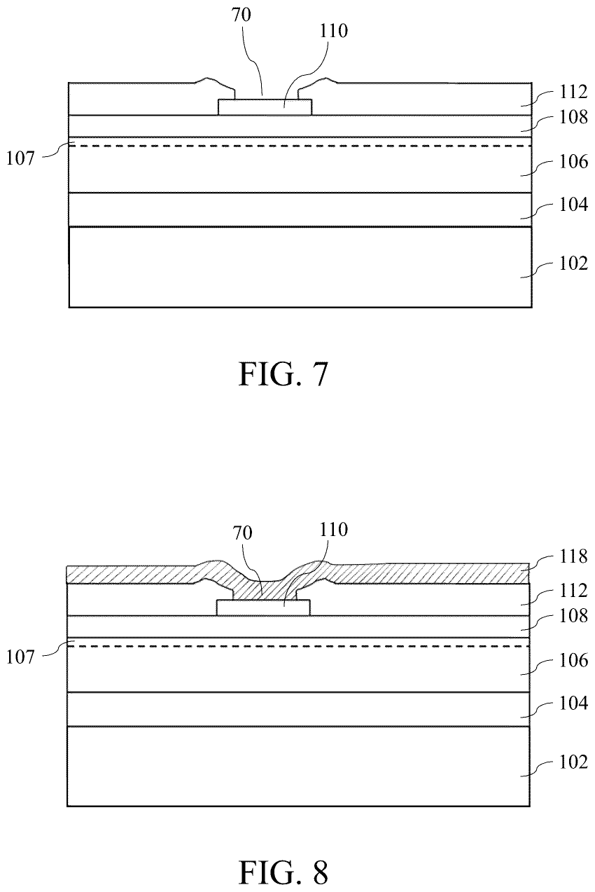

Referring to FIG. 6 and FIG. 7, the first photoresist mask 115 is stripped using known etch techniques and etch chemistries. The first photoresist mask 115 may, for example, be stripped by oxygen-based plasma ashing.

Referring to FIG. 8, a gate metal layer 118 is formed to cover the first dielectric layer 112 and fill the gate contact opening 70. The gate metal layer 118 may be formed by, for example, CVD, atomic layer deposition (ALD), PVD (e.g., sputtering or evaporation). In some embodiments, the gate metal layer 118 may have a multilayer structure.

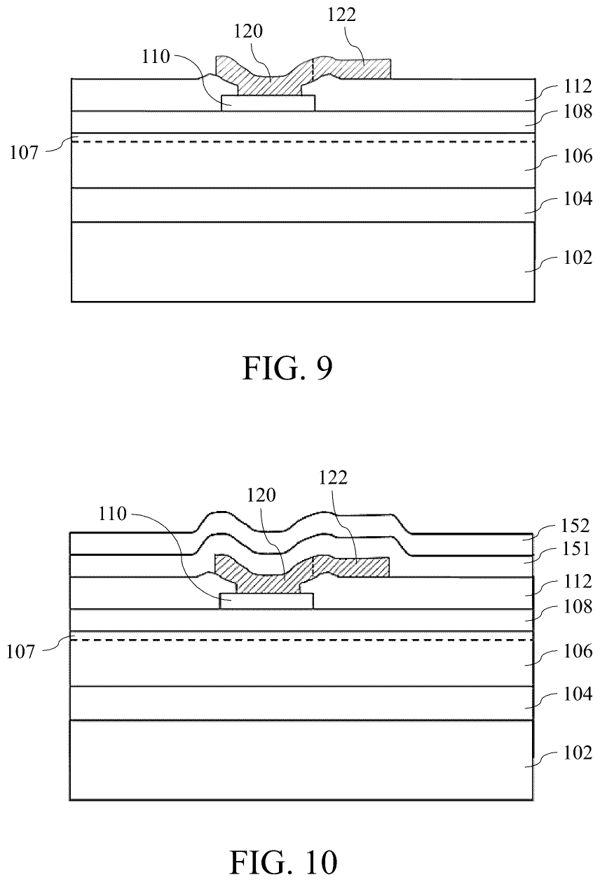

Referring to FIG. 9, the gate metal layer 118 is patterned to form a gate electrode 120 connected to the gate contact 110 and a gate field plate 122 connected to the gate electrode 120. Since the first dielectric layer 112 near the gate contact 110 in the present disclosure becomes flatter and thinner, the control of the electric field under the gate field plate 122 is improved (that is, the field plate effect becomes better).

In some embodiments, the gate contact 110 and the gate electrode 120 form a Schottky contact. For example, the gate contact 110 comprises p-type gallium nitride (PGaN), and the gate electrode 120 is a stacked structure of TiN/AlCu/TiN, in which a TiN film, a AlCu film and a TiN film are laminated in that order from the gate contact 110, or W/TiN/AlCu/TiN in which a W film, a TiN film, a AlCu film and a TiN film are laminated in that order from the gate contact 110. In some embodiments, the gate contact 110 and the gate electrode 120 form an ohmic contact. For example, the gate contact 110 comprises p-type gallium nitride, and the gate electrode 120 is a stacked structure of Ni/TiN/AlCu/TiN in which a Ni film, a TiN film, a AlCu film and a TiN film are laminated in that order from the gate contact 110.

FIG. 10 to FIG. 18 are cross-sectional views illustrating that a source electrode and a drain electrode are formed on opposite sides of the gate contact in a method of manufacturing a semiconductor device according to an embodiment of the present disclosure. In this embodiment, a source electrode 130 and a drain electrode 140 are formed on opposite sides of the gate contact 110 after patterning the gate metal layer 118, wherein one end of the gate field plate 122 is connected to the gate electrode 120, the other end of the gate field plate 122 extends toward the drain electrode 140, and the source electrode 130 and the drain electrode 140 extend through the first dielectric layer 112 and the barrier layer 108 into the channel layer 106, and the detailed description is as follows.

Referring to FIG. 10, after the gate electrode 120 and the gate field plate 122 are formed, a second dielectric layer 151 is formed over the gate electrode 120, the gate field plate 122 and the first dielectric layer 112, and then a second photoresist layer 152 is formed over the second dielectric layer 151, wherein the second dielectric layer 151 may be an inter-layer dielectric (ILD) layer. The material of the second dielectric layer 151 may include a low-k dielectric material, such as phosphosilicate glass (PSG), borophosphosilicate glass (BPSG), fluorosilicate glass (FSG), Spin-On-Glass, Spin-On-Polymers, silicon carbon material, a combination thereof, or the like, and the material of the second dielectric layer 151 may be the same as the material of the first dielectric layer 112. The second dielectric layer 151 may be formed by any suitable method, such as spin-on coating, CVD, PECVD, PVD, or the like. The second photoresist layer 152 may include a photoresist material and a solvent, wherein the photoresist material includes a polymer. The second photoresist layer 152 may be deposited by spin-on coating or other suitable technique.

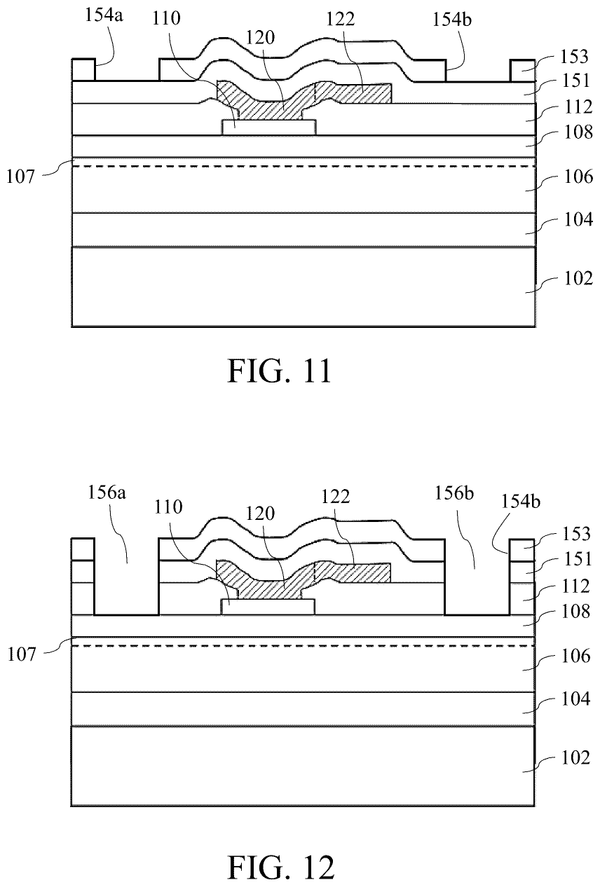

Referring to FIG. 11, the second photoresist layer 152 is patterned through exposure and development to form a second photoresist mask 153 with a first hole pattern 154a and a second hole pattern 154b, wherein the first hole pattern 154a and the second hole pattern 154b are formed at locations corresponding to the opposite sides of the gate contact 110. Referring to FIG. 12, an etching process (e.g., a dry etching process or a wet etching process) is performed using the first hole pattern 154a and the second hole pattern 154b to etch the first dielectric layer 112 and the second dielectric layer 151 to form a first opening 156a and a second opening 156b in the first dielectric layer 112 and the second dielectric layer 151.

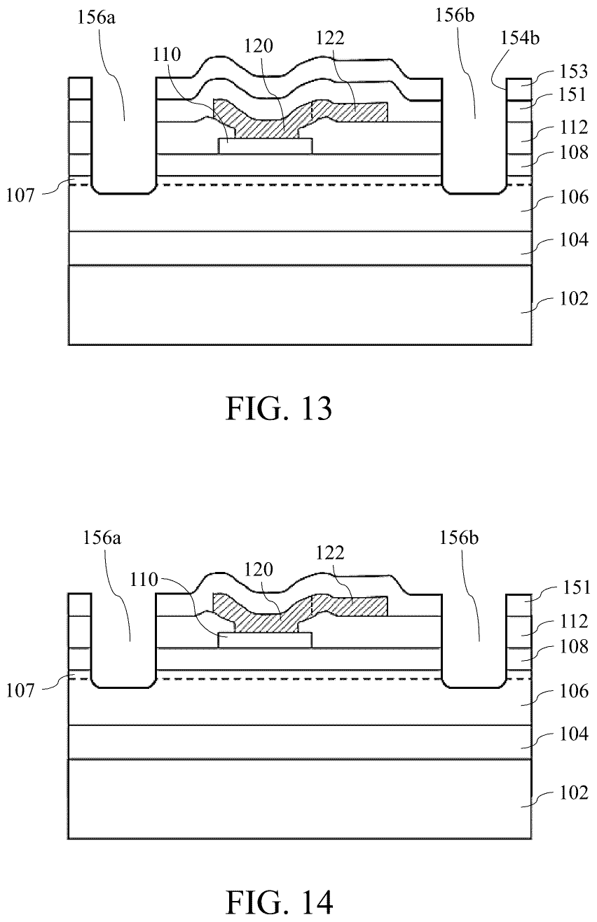

Referring to FIG. 13, a dry etching process is performed using the first hole pattern 154a and the second hole pattern 154b to etch through the barrier layer 108 and the 2DEG layer 107 into the channel layer 106 (that is, the first opening 156a and the second opening 156b extend through the first dielectric layer 112, the second dielectric layer 151, the barrier layer 108 and the 2DEG layer 107 into the channel layer 106). Referring to FIG. 13 and FIG. 14, the second photoresist mask 153 is stripped using known etch techniques and etch chemistries. The second photoresist mask 153 may, for example, be stripped by oxygen-based plasma ashing.

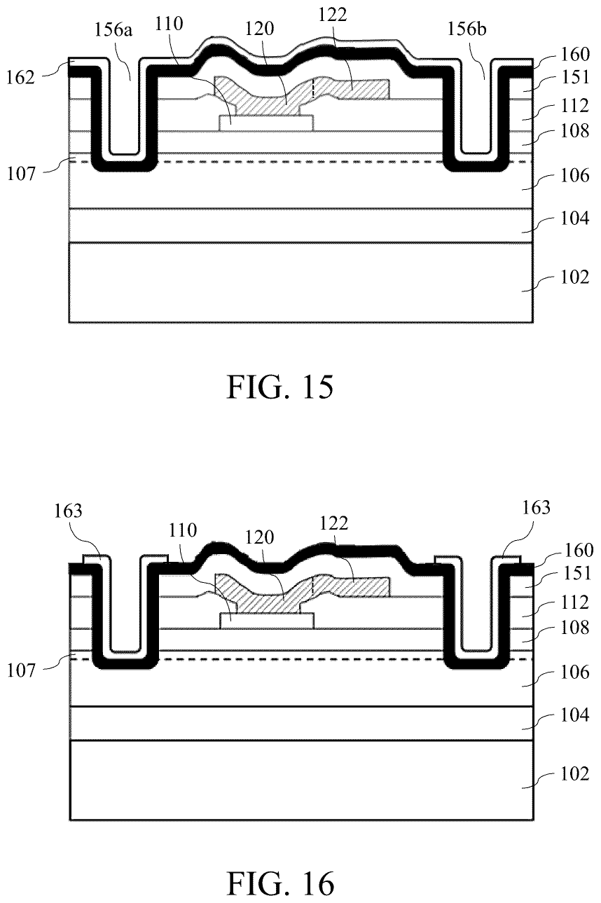

Referring to FIG. 15, a conductive material layer 160 and a third photoresist layer 162 are formed over the second dielectric layer 151, the first opening 156a and the second opening 156b in order, wherein the conductive material layer 160 may be formed by a deposition process, such as PVD (e.g. sputtering or evaporation), and the third photoresist layer 162 may be deposited by spin-on coating or other suitable technique. The material of the conductive layer 160 may include the material of the gate metal layer 118 described above.

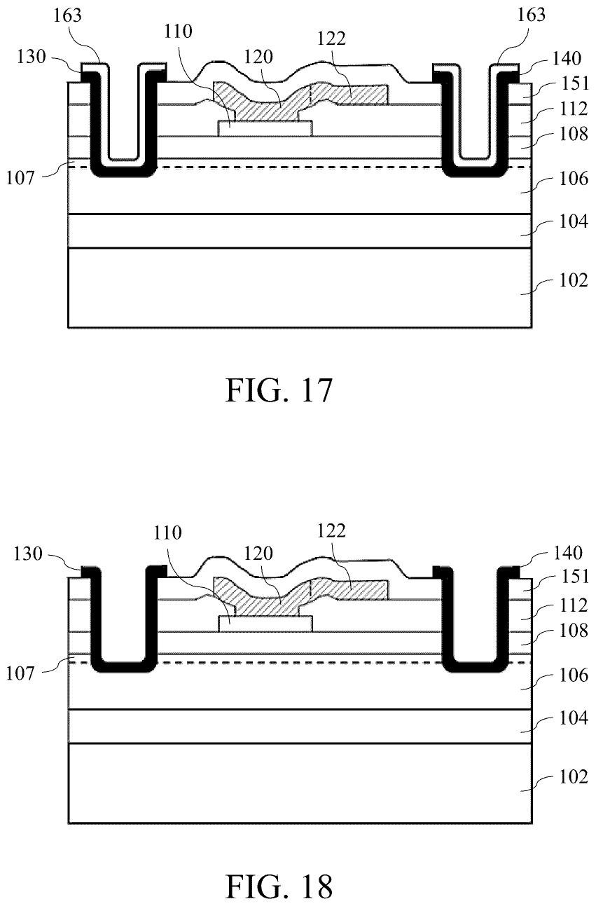

Referring to FIG. 15 and FIG. 16, the third photoresist layer 162 is patterned through exposure and development to form a third photoresist mask 163. Referring to FIG. 16 and FIG. 17, a dry etching process is performed using the third photoresist mask 163 to etch the conductive material layer 160 not cover by the third photoresist mask 163 to form the source electrode 130 and the drain electrode 140, wherein the source electrode 130 and the drain electrode 140 are connected to the 2DEG layer 107. Referring to FIG. 17 and FIG. 18, the third photoresist mask 163 is stripped using known etch techniques and etch chemistries. The third photoresist mask 163 may, for example, be stripped by oxygen-based plasma ashing.

It should be noted that this embodiment is not intended to limit the present disclosure since the production process of the gate electrode 120 and the production process of the source electrode 130 and the drain electrode 140 are independent processes. For example, the source electrode 130 and the drain electrode 140 are formed on opposite sides of the gate contact 110 after forming the first dielectric layer 112, and then the production process of the gate electrode 120 is performed according to the description of the above embodiment. For those skilled in the art, the details of forming the source electrode 130 and the drain electrode 140 on opposite sides of the gate contact 110 after forming the first dielectric layer 112, and then performing the production process of the gate electrode 120 can be understood based on the description of the above embodiment, and shall be omitted herein.

In summary, in the embodiments of the present disclosure, based on the anisotropic characteristic of the dry etching process and the isotropic characteristic of the first wet etching process and the second wet etching process, performing the first wet etching process, the dry etching process, and the second wet etching process on the first dielectric layer using the hole pattern in order can not only form the gate contact opening exposes the portion of the gate contact, but also flatten and thin the first dielectric layer near the gate contact, thereby avoiding the damage of the gate contact, increasing the field plate effect and improving the performance of the semiconductor device. In addition, by controlling the sum of the etched depth of the first dielectric layer etched by the first wet etching process and the etched depth of the first dielectric layer etched by the second wet etching process, the flatness and thickness of the first dielectric layer near the gate contact can be controlled based on the isotropic characteristic of the first wet etching process and the second wet etching process. Besides, the gate contact and the gate electrode may form a Schottky contact or an ohmic contact.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A method of manufacturing a semiconductor device, the method comprising:
growing a buffer layer, a channel layer, and a barrier layer on a substrate layer in order;
forming a gate contact on a portion of the barrier layer;
forming a first dielectric layer, and a first photoresist layer over the gate contact and the barrier layer not covered by the gate contact in order;
patterning the first photoresist layer to form a first photoresist mask with a hole pattern;
performing a first wet etching process, a dry etching process, and a second wet etching process using the hole pattern to etch the first dielectric layer in order to form a gate contact opening which exposes a portion of the gate contact;
stripping the first photoresist mask;
forming a gate metal layer to cover the first dielectric layer and fill the gate contact opening; and
patterning the gate metal layer to form a gate electrode connected to the gate contact and a gate field plate connected to the gate electrode.

2. The method of manufacturing the semiconductor device according to claim 1, wherein a sum of an etched depth of the first dielectric layer etched by the first wet etching process and an etched depth of the first dielectric layer etched by the second wet etching process is from about forty percent to about seventy percent of a thickness of the first dielectric layer.

3. The method of manufacturing the semiconductor device according to claim 1, wherein the step of performing the first wet etching process using the hole pattern to etch the first dielectric layer comprises: performing the first wet etching process using the hole pattern to etch the first dielectric layer to form a recess with a depth between about twenty percent and about fifty percent of a thickness of the first dielectric layer.

4. The method of manufacturing the semiconductor device according to claim 1, wherein the step of performing the dry etching process using the hole pattern to etch the first dielectric layer comprises: performing the dry etching process using the hole pattern to etch the first dielectric layer to form a trench with a depth between about thirty percent and about sixty percent of a thickness of the first dielectric layer.

5. The method of manufacturing the semiconductor device according to claim 1, wherein the step of performing the second wet etching process using the hole pattern to etch the first dielectric layer comprises: performing the second wet etching process using the hole pattern to etch a remaining thickness of the first dielectric layer, which is between about 20 percent and about 50 percent of a thickness of the first dielectric layer, to form the gate contact opening.

6. The method of manufacturing the semiconductor device according to claim 1, wherein the second wet etching process is performed with a total time including an etching time and an over-etching time, the over-etching time is in a range from about fifty percent to about one hundred percent of the etching time, and the etching time is a time for etching a remaining thickness of the first dielectric layer to form the gate contact opening.

7. The method of manufacturing the semiconductor device according to claim 1, wherein the gate contact and the gate electrode form a Schottky contact.

8. The method of manufacturing the semiconductor device according to claim 7, wherein the gate contact comprises p-type gallium nitride (PGaN), and the gate electrode is a stacked structure of TiN/AlCu/TiN or W/TiN/AlCu/TiN.

9. The method of manufacturing the semiconductor device according to claim 1, wherein the gate contact and the gate electrode form an ohmic contact.

10. The method of manufacturing the semiconductor device according to claim 9, wherein the gate contact comprises p-type gallium nitride, and the gate electrode is a stacked structure of Ni/TiN/AlCu/TiN.

11. The method of manufacturing the semiconductor device according to claim 1, further comprising: forming a source electrode and a drain electrode on opposite sides of the gate contact after forming the first dielectric layer, wherein one end of the gate field plate is connected to the gate electrode, the other end of the gate field plate extends toward the drain electrode, and the source electrode and the drain electrode extend through the first dielectric layer and the barrier layer into the channel layer.

12. The method of manufacturing the semiconductor device according to claim 1, further comprising: forming a source electrode and a drain electrode on opposite sides of the gate contact after patterning the gate metal layer, wherein one end of the gate field plate is connected to the gate electrode, the other end of the gate field plate extends toward the drain electrode, and the source electrode and the drain electrode extend through the first dielectric layer and the barrier layer into the channel layer.

13. The method of manufacturing the semiconductor device according to claim 1, wherein the first wet etching process and the second wet etching process are performed by using at least one of a hydrogen fluoride (HF) solution and a buffered oxide etchant (BOE).

14. The method of manufacturing the semiconductor device according to claim 13, wherein the buffered oxide etchant is a solution of HF/NH₄F in a volume ratio of 20:1 mixed with water.
